(19) United States
(12) Patent Application Publication
(10) Pub. No.: US 2024/0429245 A1
(43) Pub. Date: Dec. 26, 2024

(54) ARRAY SUBSTRATE AND DISPLAY PANEL

(71) Applicants: HEFEI VISIONOX TECHNOLOGY CO., LTD., Hefei (CN); KUNSHAN GO-VISIONOX OPTO-ELECTRONICS CO., LTD., Kunshan (CN)

(72) Inventors: Hung Chih YU, Hefei (CN); Xiujian ZHU, Hefei (CN)

(21) Appl. No.: 18/823,923

(22) Filed: Sep. 4, 2024

Related U.S. Application Data
(63) Continuation of application No. PCT/CN2022/130841, filed on Nov. 9, 2022.

(30) Foreign Application Priority Data
Jul. 12, 2022 (CN) 202210819815.7

(51) Int. Cl. H01L 27/12

(52) U.S. Cl. CPC H01L 27/124; H01L 27/1225; H01L 27/1248

(57) ABSTRACT

An array substrate includes a substrate, a compensation layer, an insulating layer and an active layer. The compensation layer is disposed on a side of the substrate. The insulating layer is disposed on a side of the compensation layer away from the substrate and covers the compensation layer. The active layer is disposed on a side of the insulating layer away from the substrate. A vertical projection of the compensation layer on the substrate overlaps a vertical projection of the active layer on the substrate, and the compensation layer is configured to compensate for a threshold voltage of a thin-film transistor of the array substrate.

### CROSS-REFERENCES TO RELATED APPLICATION(S)

This application is a continuation of International Application No. PCT/CN2022/130841, filed on Nov. 9, 2022, which claims priority to Chinese Patent Application No. 202210819815.7 filed with the China National Intellectual Property Administration (CNIPA) on Jul. 12, 2022, the disclosures of which are incorporated herein by reference in their entireties.

### TECHNICAL FIELD

The present application relates to the field of display technology and, in particular, to an array substrate and a display panel.

### BACKGROUND

With the development of display technology, display panels are increasingly widely used, and accordingly, the requirements for the display panels are also increasing.

A display panel generally includes pixel circuits and light-emitting elements. The pixel circuits drive the light-emitting elements to emit light, implementing the function of image display. A pixel circuit includes thin-film transistors. However, the existing thin-film transistors have unstable characteristics, affecting the display effect of the display panel.

### SUMMARY

The present application provides an array substrate and a display panel to improve the display effect of the display panel.

According to an aspect of the present application, an array substrate is provided. The array substrate includes a substrate, a compensation layer, an insulating layer and an active layer. The compensation layer is disposed on a side of the substrate. The insulating layer is disposed on a side of the compensation layer away from the substrate and covers the compensation layer. The active layer is disposed on a side of the insulating layer away from the substrate. A vertical projection of the compensation layer on the substrate overlaps a vertical projection of the active layer on the substrate, and the compensation layer is configured to compensate for a threshold voltage of a thin-film transistor of the array substrate.

According to another aspect of the present application, a display panel is provided. The display panel includes the array substrate provided in any embodiment of the present application. A pixel circuit is disposed on the array substrate.

The array substrate provided in the embodiment of the present application includes the substrate and the compensation layer and the active layer which are disposed on a side of the substrate. The compensation layer is disposed between the substrate and the active layer and is covered by the insulating layer. The vertical projection of the compensation layer on the substrate overlaps the vertical projection of the active layer on the substrate. According to the embodiment of the present application, the compensation layer is disposed in the thin-film transistor to block at least a part of the active layer, thereby avoiding the attack by some electrons or holes on the active layer and preventing electrons or holes from acting on the active layer and thus affecting a threshold voltage of the thin-film transistor. In this manner, positive bias temperature stress (PBTS) or negative bias temperature stress (NBTS) of the thin-film transistor is improved, which is conducive to improving the display effect of the display panel including the thin-film transistor.

It is to be understood that the content described in this section is neither intended to identify key or critical features of the embodiments of the present application nor intended to limit the scope of the present application. Other features of the present application become easily understood through the description provided hereinafter.

### BRIEF DESCRIPTION OF DRAWINGS

To illustrate embodiments of the present application more clearly, drawings used in description of the embodiments are described simply hereinafter. Apparently, the drawings described hereinafter illustrate part of embodiments of the present application, and those of ordinary skill in the art may obtain other drawings according to the drawings described hereinafter on the premise that no creative work is done.

FIG. 1 is a structural diagram of an array substrate according to an embodiment of the present application;

FIG. 2 is a structural diagram of another array substrate according to an embodiment of the present application;

FIG. 3 is a structural diagram of another array substrate according to an embodiment of the present application;

FIG. 4 is a structural diagram of another array substrate according to an embodiment of the present application;

FIG. 5 is a structural diagram of another array substrate according to an embodiment of the present application;

FIG. 6 is a structural diagram of another array substrate according to an embodiment of the present application;

FIG. 7 is a structural diagram of another array substrate according to an embodiment of the present application;

FIG. 8 is a structural diagram of another array substrate according to an embodiment of the present application;

FIG. 9 is a structural diagram of another array substrate according to an embodiment of the present application;

FIG. 10 is a structural diagram of a pixel circuit according to an embodiment of the present application;

FIG. 11 is a structural diagram of another pixel circuit according to an embodiment of the present application;

FIG. 12 is a structural diagram of another pixel circuit according to an embodiment of the present application; and

FIG. 13 is a structural diagram of a display panel according to an embodiment of the present application.

### DETAILED DESCRIPTION

To make embodiments of the present disclosure better understood by those skilled in the art, the embodiments of the present application will be described clearly and completely in conjunction with the drawings of the embodiments of the present application. Apparently, the embodiments described below are part, not all, of embodiments of the present application. Based on the embodiments of the present application, all other embodiments obtained by those of ordinary skill in the art without creative work are within the scope of the present application.

It is to be noted that terms “first”, “second” and the like in the description, claims and drawings of the present application are used for distinguishing between similar objects and are not necessarily used for describing a particular order or sequence. It is to be understood that data used in this manner is interchangeable in appropriate cases so that the embodiments of the present application described herein can also be implemented in an order not illustrated or described herein. In addition, terms “comprising”, “including” and any other variations thereof are intended to encompass a non-exclusive inclusion.

As described in the background, thin-film transistors in the related art have unstable characteristics, which can easily affect the display effect of the display panel. It is found that the reason for the preceding situation is that, when the pixel circuit formed by the thin-film transistor and the thin-film transistor is used for the turning-on or turning-off function, the PBTS or the NBTS of the thin-film transistor has a greater impact on the display quality and the display effect, which easily causes phenomena such as image sticking, low-frequency flickering or greenish images. During normal display, it is expected that the absolute value of PBTS or NBTS of the thin-film transistors is relatively small so that the display effect is improved. However, in the manufacturing process of the thin-film transistor, the gate pattern of the thin-film transistor cannot completely cover the pattern of the active layer, resulting in an unblocked region of the pattern of the active layer. This unblocked region is easily affected by electrons and holes, causing a drift in the threshold characteristics of the thin-film transistor, resulting in the relatively large absolute value of PBTS or NBTS of the thin-film transistor, seriously affecting the image quality and reducing the display effect.

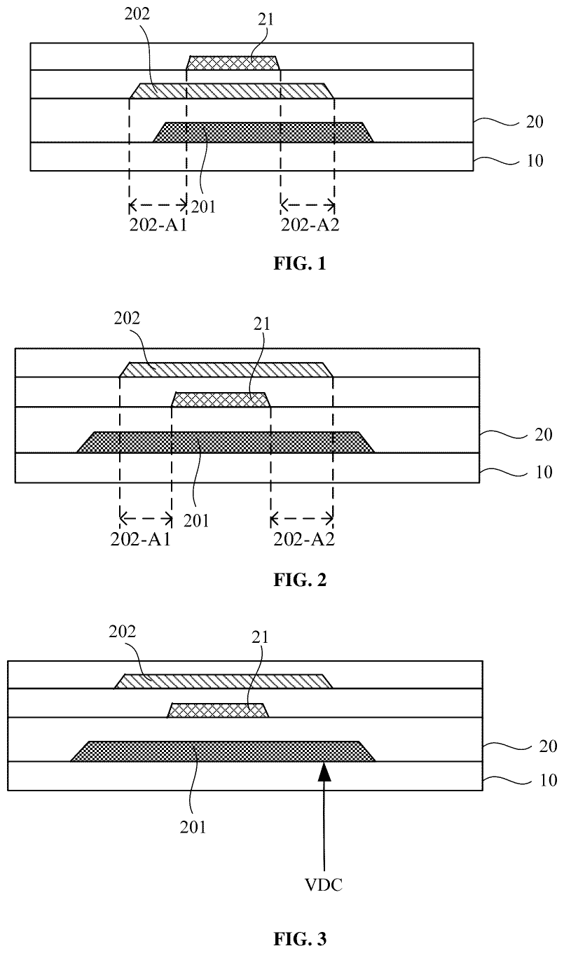

For the preceding situation, an embodiment of the present application provides an array substrate including a thin-film transistor to alleviate the threshold drift phenomenon of the thin-film transistor and reduce the PBTS or NBTS of the thin-film transistor. FIG. 1 is a structural diagram of an array substrate according to an embodiment of the present application. Referring to FIG. 1, the array substrate includes a substrate 10, a compensation layer 201, an insulating layer 20 and an active layer 202. The compensation layer 201 is disposed on a side of the substrate 10. The insulating layer 20 is disposed on a side of the compensation layer 201 away from the substrate 10 and covers the compensation layer 201. The active layer 202 is disposed on a side of the insulating layer 20 away from the substrate 10. A vertical projection of the compensation layer 201 on the substrate 10 overlaps a vertical projection of the active layer 202 on the substrate 10, and the compensation layer 201 is configured to compensate for a threshold voltage of a thin-film transistor.

Specifically, the substrate 10 serves as a support to support the thin-film transistor. A gate layer 21 is further disposed on the substrate 10. The gate layer 21 is configured to form a gate electrode of the thin-film transistor. The gate layer 21 is disposed opposite the active layer 202. For example, as shown in FIG. 1, the gate layer 21 is disposed on a side of the active layer 202 away from the substrate 10, and a channel region may be formed at a region where the active layer 202 is directly opposite the gate layer 21. To avoid a short between the gate layer 21 and the active layer 202, a gate insulating layer is disposed between the gate layer 21 and the active layer 202.

Of course, the gate layer 21 may also be disposed below the active layer 202. FIG. 2 is a structural diagram of another array substrate according to an embodiment of the present application. Referring to FIG. 2, the gate layer 21 is disposed on a side of the active layer 202 close to the substrate 10. Here, regardless of whether the gate layer 21 is disposed above or below the active layer 202, the gate layer 21 cannot completely block the active layer 202. Specifically, as shown in FIG. 1 or FIG. 2, a non-overlapping portion exists between a vertical projection of the gate layer 21 on the substrate 10 and the vertical projection of the active layer 202 on the substrate 10, where the non-overlapping portion includes a first portion 202-A1 and a second portion 202-A2. The substrate 10 is generally a flexible polyimide (PI) substrate, to which fluorine is generally introduced to reduce the polarizability of PI. In subsequent processes, ionization can cause the accumulation of electrons or holes, such as fluorine ions, in the PI substrate. These accumulated electrons or holes are prone to attack the active layer 202, thereby affecting the threshold voltage of the thin-film transistor.

In the embodiment, the compensation layer 201 is disposed on the substrate 10, and the compensation layer 201 is disposed on the side of the active layer 202 close to the substrate 10. Regardless of whether the gate layer 21 is disposed above or below the active layer 202, the gate layer 21 is disposed on the side of the compensation layer 201 away from the substrate 10. The vertical projection of the compensation layer 201 on the substrate 10 at least partially overlaps the vertical projection of the active layer 202 on the substrate 10, that is, the compensation layer 201 can at least partially block the active layer 202, thereby blocking a part of the active layer 202 that is not blocked by the gate layer 21. Specifically, the vertical projection of the compensation layer 201 on the substrate 10 covers at least the non-overlapping portion which includes the first portion 202-A1 and the second portion 202-A2. For example, as shown in FIG. 1, the vertical projection of the compensation layer 201 on the substrate 10 covers part of the first portion 202-A1 and the entire second portion 202-A2. For another example, as shown in FIG. 2, the vertical projection of the compensation layer 201 on the substrate 10 covers the entire first portion 202-A1 and the entire second portion 202-A2. In this manner, the impact of the accumulated electrons of holes in the substrate 10 on the active layer 202 and the resulting threshold voltage drift of the thin-film transistor are prevented, and thus the threshold voltage of the thin-film transistor is compensated for.

It is to be understood that to better prevent the active layer 202 from being attacked by the accumulated electrons or holes in the substrate 10, the projection of the compensation layer 201 on the substrate should cover at least the part of the active layer 202 that is not blocked by the gate layer 21.

The array substrate provided in the embodiment of the present application includes the substrate and the compensation layer, the insulating layer and the active layer which are all disposed on a side of the substrate. The compensation layer is disposed between the substrate and the active layer and is covered by the insulating layer. The vertical projection of the compensation layer on the substrate overlaps the vertical projection of the active layer on the substrate. In the embodiment of the present application, the compensation layer is disposed in the array substrate to block at least a part of the active layer, thereby avoiding the attack by some electrons or holes on the active layer and preventing electrons or holes in the substrate from acting on the active layer and thus affecting the threshold voltage of the thin-film transistor. In this manner, the PBTS or NBTS of the thin-film transistor is improved, which is conducive to improving the display effect of the display panel including the thin-film transistor.

With continued reference to FIG. 2, in a preferred implementation provided in the embodiment of the present application, the vertical projection of the compensation layer 201 on the substrate 10 overlaps at least the vertical projection of the active layer 202 on the substrate 10, that is, the compensation layer 201 can completely block the active layer 202. In this manner, electrons or holes in the substrate 10 cannot penetrate through the compensation layer to act on the active layer 202, thereby ensuring the blocking effect on the active layer 202 and thus improving the effect of compensating for the threshold voltage of the thin-film transistor.

In the embodiment, the substrate 10 may be a flexible substrate. For example, the substrate 10 may be made of the polyimide (PI) material. In the related art, since the gate layer 21 cannot completely block the active layer, under the act of the characteristics of the flexible material such as PI, fluoride ions in the substrate 10 can directly act on the active layer 202, affecting the electric field distribution inside the active layer 202, thereby causing the threshold voltage drift of the thin-film transistor. The compensation layer 201 is added to block the active layer 202, so that the impact of ions in the substrate 10 on the active layer 202 can be effectively blocked, and the drift of the threshold voltage of the thin-film transistor can be prevented.

Optionally, the material of the compensation layer 201 may be amorphous silicon or metal, which can effectively block ions or other electrons in the substrate 10 from entering the active layer 202, where the metal material may include titanium, molybdenum, aluminum or alloys thereof.

In the embodiment, if the material of the active layer 201 is metal, the compensation layer 201 may be connected to a compensation voltage so that an electric field is generated between the compensation layer 201 and the active layer 202. Through the electric field, the threshold voltage of the thin-film transistor is reversely biased so that the drift of the threshold voltage caused by electrons or holes is compensated for. FIG. 3 is a structural diagram of another array substrate according to an embodiment of the present application. Referring to FIG. 3, on the basis of the preceding embodiments, the compensation layer 201 is connected to a direct current voltage VDC so that the drift of the threshold voltage is compensated for. Here, the compensation layer 201 serves as an electrode of the thin-film transistor, so that the thin-film transistor forms a four-terminal (a gate, a source, a drain and the electrode formed by the compensation layer 201) device. The direct current voltage VDC is applied to the compensation layer 201 to alleviate the threshold voltage drift.

Specifically, in the embodiment, the material of the active layer 202 is a metal oxide, such as the indium gallium zinc oxide (IGZO). When electrons (such as fluorine ions) in the substrate 10 act on the IGZO active layer 202, the threshold voltage of the thin-film transistor will be negatively biased. A compensation voltage VDC is applied to the compensation layer 201, so that an electric field is formed between the compensation layer 201 and the active layer 202; the electric field distribution of the active layer 202 is adjusted through the electric field, and then the threshold voltage is adjusted to be biased to an opposite direction, so that the negative bias of the threshold voltage is compensated for.

In the embodiment, the compensation voltage VDC is a direct current negative voltage, and the voltage value may be set according to the thickness between the compensation layer 201 and the active layer 202. The threshold voltage of an IGZO thin-film transistor is a positive voltage. A negative voltage is applied to the compensation layer 201, so that the threshold voltage of the thin-film transistor can be positively biased, and thus the negative bias of the threshold voltage caused by electrons or holes is compensated for. In the specific implementation process, the threshold voltage of the thin-film transistor can be adjusted to around 0V through the direct current voltage VDC, so that the PBTS of the thin-film transistor is less than 1V and thus expectations are satisfied.

Compared to a Low Temperature Polycrystalline Silicon (LTPS) thin-film transistor, the difficulty of realizing an improving process of the uniformity of the threshold voltage of the IGZO thin-film transistor is big. The IGZO thin-film transistor is usually used as a switching transistor. The pixel circuit requires as little PBTS or NBTS of the switching transistor as possible to improve the display effect. In the embodiment, to ensure that electrons (fluorine ions) in the substrate 10 do not act on the active layer 202 (some electrons may enter the active layer 202 due to incomplete blocking), a direct current negative voltage is applied to the compensation layer 201 to positively bias the threshold voltage of the thin-film transistor, so that the negative bias of the threshold voltage caused by the impact of electrons on the active layer 202 is compensated for. Therefore, setting the compensation layer 201 can greatly reduce the difficulty of the process.

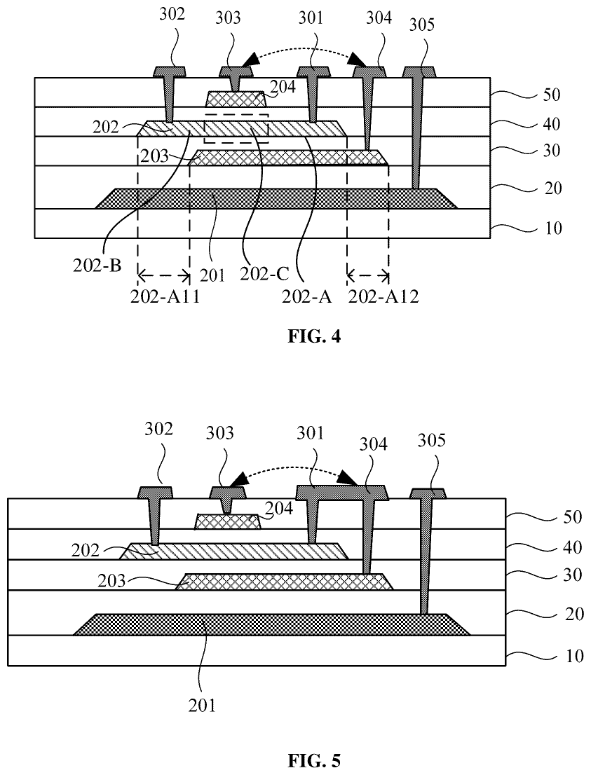

FIG. 4 is a structural diagram of another array substrate according to an embodiment of the present application. Referring to FIG. 4, on the basis of the preceding embodiments, the array substrate further includes a gate layer and a first gate insulating layer 30, a second gate insulating layer 40 and an interlayer insulating layer 50, where the first gate insulating layer 30, the second gate insulating layer 40 and the interlayer insulating layer 50 are laminated on the insulating layer 20, and the gate layer includes a first gate layer 203 and a second gate layer 204. The first gate layer 203 is disposed on a surface of the side of the insulating layer 20 away from the substrate and is covered by the first gate insulating layer 30. The second gate insulating layer 40 covers the active layer 202. The second gate layer 204 is disposed on a surface of a side of the second gate insulating layer 40 away from the first gate insulating layer 30 and is covered by the interlayer insulating layer 50. That is, the first gate layer 203 is disposed on the side of the compensation layer 201 away from the substrate 10, and the first gate insulating layer 30 covers the first gate layer 203; the second gate insulating layer 40 is disposed on the side of the active layer 202 away from the substrate 10, and the second gate insulating layer 40 covers the active layer 202; the second gate layer 204 is disposed on a side of the second gate insulating layer 40 away from the substrate 10.

Specifically, if the compensation layer 201 is made of metal, to avoid the short circuit between the compensation layer 201 and the first gate layer 203, the insulating layer 20 is disposed between the compensation layer 201 and the first gate layer 203 to achieve the insulation purpose. In the embodiment, the first gate layer 203 may be a bottom gate of the thin-film transistor, and the second gate layer 204 may be a top gate of the thin-film transistor. Ion implantation is performed on the active layer 202, so that a source region and a drain region can be formed on two sides of the active layer 202 respectively, while a region where no ion is implanted forms a channel region. The second interlayer insulating layer 50 is disposed on a side of the second gate layer 204 away from the substrate 10. A source electrode is formed by leading out the source region through the source layer 301, and a drain electrode is formed by leading out the drain region through the drain layer 302 (the source layer 301 is the source electrode, and the drain layer 302 is the drain electrode). The first gate layer 203 is led out through a first connecting line 304, the second gate layer 204 is led out through a second connecting line 303, and the compensation layer 201 is led out through a third connecting line 305, so that the connection of the thin-film transistor is achieved through various connecting lines. The first gate layer 203 is a first gate electrode of the thin-film transistor, the second gate layer 204 is a second gate electrode of the thin-film transistor, and the compensation layer 201 is a compensation electrode of the thin-film transistor.

With continued reference to FIG. 4, in the embodiment, the first gate layer 203 is connected to the second gate layer 204, which can improve the electron mobility of the thin-film transistor. In other words, the first gate electrode and the second gate electrode are connected together to form a first terminal of the thin-film transistor. The compensation electrode serves as a second terminal of the thin-film transistor, the source layer 301 serves as a third terminal of the thin-film transistor, and the drain layer 302 serves as a fourth terminal of the thin-film transistor. In practical applications, the compensation electrode is connected to the compensation voltage VDC to compensate for the threshold voltage bias of the thin-film transistor, thereby reducing the PBTS or NBTS of the thin-film transistor.

With further continued reference to FIG. 4, a non-overlapping portion exists between a vertical projection of the first gate layer 203 on the substrate 10 and the vertical projection of the active layer 202 on the substrate 10, where the non-overlapping portion includes a first portion 202-A11 and a second portion 202-A12 in FIG. 4. The vertical projection of the compensation layer 201 on the substrate 10 covers at least the non-overlapping portion which includes the first portion 202-A11 and the second portion 202-A12. For example, the vertical projection of the compensation layer 201 on the substrate 10 covers the entire first portion 202-A11 and the entire second portion 202-A12.

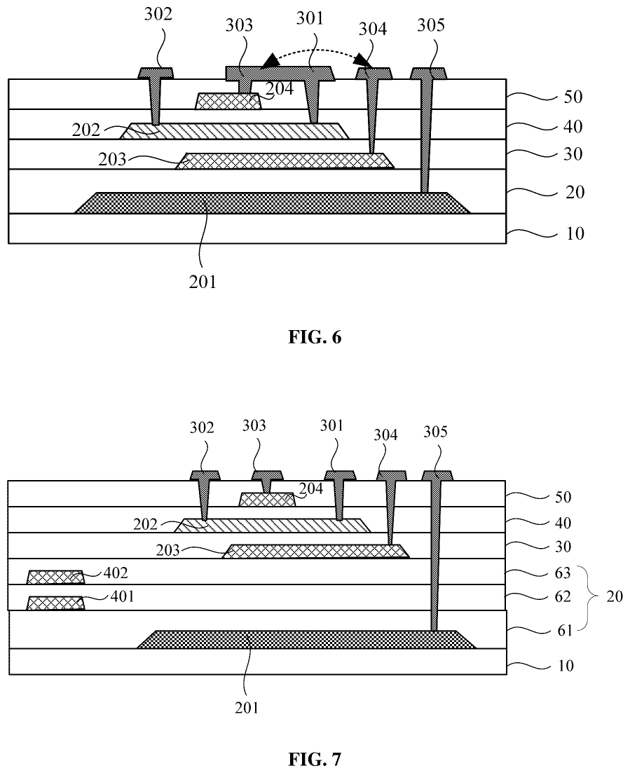

FIG. 5 is a structural diagram of another array substrate according to an embodiment of the present application. Referring to FIG. 5, optionally, on the basis of the preceding embodiments, the first gate layer 203 may also be connected to the source layer 301, which can improve the reliability of the thin-film transistor. Here, the first gate electrode and the second gate electrode are connected together to form the first terminal of the thin-film transistor, the compensation electrode serves as the second terminal of the thin-film transistor, the source layer 301 serves as the third terminal of the thin-film transistor, and the drain layer 302 serves as the fourth terminal of the thin-film transistor. In practical applications, the compensation electrode is connected to the compensation voltage VDC to compensate for the threshold voltage bias of the thin-film transistor, thereby reducing the PBTS or NBTS of the thin-film transistor.

FIG. 6 is a structural diagram of another array substrate according to an embodiment of the present application. Referring to FIG. 6, optionally, the second gate layer 204 may also be connected to the source layer 301, which can improve the reliability of the thin-film transistor. As a four-terminal device, the thin-film transistor has the same beneficial effects as the thin-film transistor shown in FIG. 5.

In the embodiment, there is no limitation on the thickness between the compensation layer 201 and the active layer 202, and cases where the vertical projection of the compensation layer 201 on the substrate 10 overlaps the vertical projection of the active layer 202 on the substrate 10 are all within the scope of the present application.

Optionally, FIG. 7 is a structural diagram of another array substrate according to an embodiment of the present application. Referring to FIG. 7, the insulating layer 20 includes a first insulating sublayer 61, a second insulating sublayer 62 and a third insulating sublayer 63 which are laminated on a side of the substrate 10. The active layer 202 is disposed on a side of the third insulating sublayer 63 away from the substrate 10, that is, the first insulating sublayer 61, the second insulating sublayer 62 and the third insulating sublayer 63 are all disposed below the active layer 202. In the embodiment, the compensation layer 201 may be disposed in any layer of the first insulating sublayer 61, the second insulating sublayer 62 and the third insulating sublayer 63.

The array substrate further includes a first electrode layer 401 and a second electrode layer 402. The first electrode layer 401 is disposed on a side of the first insulating sublayer 61 away from the substrate 10 and is covered by the second insulating sublayer 62, and the second electrode layer 402 is disposed on a side of the second insulating sublayer 62 away from the first insulating sublayer 61 and is covered by the third insulating sublayer 63. The first electrode layer 401 and the second electrode layer 402 are used for forming a storage capacitor, and the second insulating sublayer 62 may serve as a dielectric layer for the storage capacitor.

In the embodiment, the compensation layer 201 may be disposed between the substrate 10 and the first insulating sublayer 61. Of course, the compensation layer 201 may also be disposed between the second insulating sublayer 62 and the first insulating sublayer 61, or between the second insulating sublayer 62 and the third insulating sublayer 63. In other words, if the first gate layer 203 is disposed below the active layer 202, the compensation layer 201 may be disposed in any film layer below the first gate layer 203.

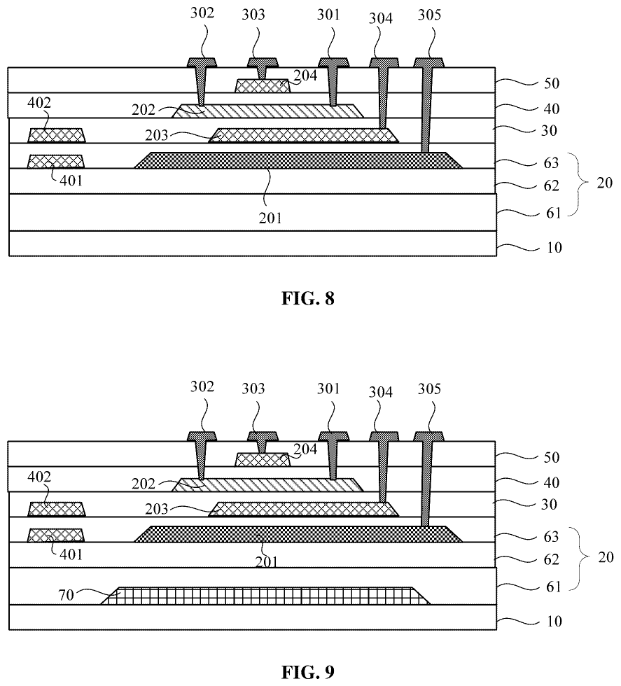

FIG. 8 is a structural diagram of another array substrate according to an embodiment of the present application. Referring to FIG. 8, on the basis of the preceding embodiments, optionally, the first gate layer 203 may be disposed in the same layer as the second electrode layer 402, which is conductive to reducing the overall thickness of the array substrate. In a preferred implementation provided in the embodiment, the compensation layer 201 is disposed between the second insulating sublayer 62 and the third insulating sublayer 63. The first electrode layer 401 is disposed in the same layer as the compensation layer 201, and the second electrode layer 402 is disposed in the same layer as the gate layer and may specifically be disposed in the same layer as the first gate layer 203. Here, the third insulating sublayer 63 serves as the dielectric layer for the storage capacitor.

In the embodiment, if the compensation layer 201 is not connected to the compensation voltage VDC, the compensation layer 201 may also be used as the first electrode layer 401, and the first gate layer 203 may also be used as the second electrode layer 402, which is conducive to reducing the processes and lowering the process difficulty.

It is to be noted that other film layers, such as a buffer layer, may be included between the substrate 10 and the first gate layer 203, and these film layers are not shown in the figures. Without affecting the function of the array substrate, the compensation layer 201 may be disposed in any film layer below the first gate layer 203.

FIG. 9 is a structural diagram of another array substrate according to an embodiment of the present application. Referring to FIG. 9, on the basis of the preceding embodiments, the array substrate further includes a blocking layer 70.

The blocking layer 70 may be disposed in any layer of the first insulating sublayer 61, the second insulating sublayer 62 and the third insulating sublayer 63 to achieve the light blocking function. For the specific working principle, reference may be made to relevant descriptions in the related art, and the specific working principle is not repeated here. In the embodiment, preferably, the blocking layer 70 may be disposed in the same layer as the compensation layer 201 so that the overall blocking effect on the array substrate is improved.

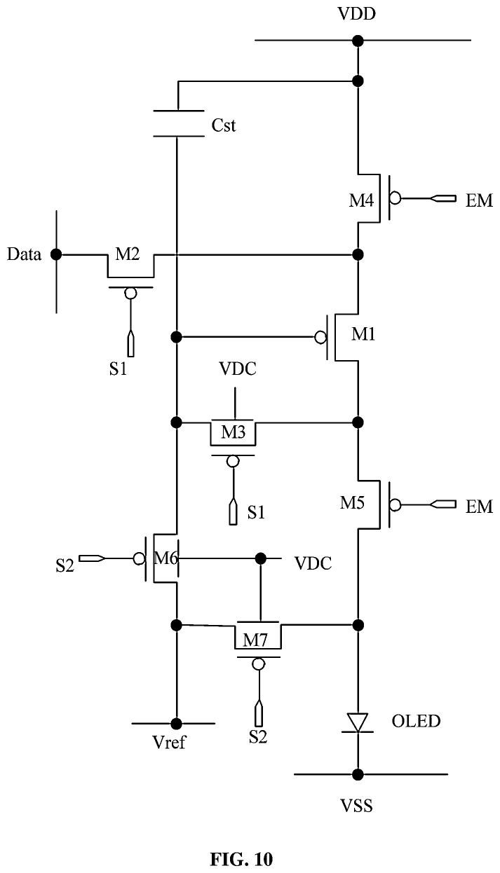

An embodiment of the present application further provides a display panel including the array substrate provided in any of the preceding embodiments. A pixel circuit is disposed on the array substrate, and the pixel circuit includes the thin-film transistor provided in any embodiment of the present application. The IGZO thin-film transistor is taken as an example. The IGZO thin-film transistor may be used as a threshold compensation transistor and an initialization transistor in the pixel circuit, which can reduce the leakage current in the pixel circuit. In the embodiment, the pixel circuit may be architectures such as 7TIC, 7T2C and 8T2C. FIG. 10 is a structural diagram of a pixel circuit according to an embodiment of the present application. The pixel circuit includes an organic light-emitting diode OLED, a drive transistor M1, a data write transistor M2, a threshold compensation transistor M3, a first light emission control transistor M4, a second light emission control transistor M5, a first initialization transistor M6, a second initialization transistor M7 and a storage capacitor Cst. The threshold compensation transistor M3, the first initialization transistor M6 and the second initialization transistor M7 are indium gallium zinc oxide (InGaZnO, that is, IGZO) transistors and each have four terminals (that is, a gate, a source, a drain and a compensation electrode). A direct current voltage VDC is applied to the compensation electrode, so that a threshold voltage of the IGZO transistor is compensated for, and the PBTS of the IGZO transistor is reduced, which is conducive to improving the reliability of the pixel circuit and then ensuring the display effect of the display panel. The specific working principle of the pixel circuit is not repeated here.

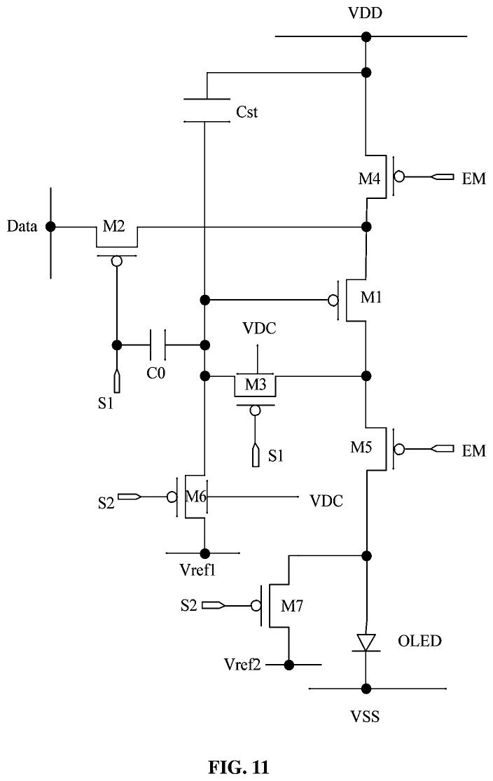

FIG. 11 is a structural diagram of another pixel circuit according to an embodiment of the present application. The pixel circuit includes an organic light-emitting diode OLED, a drive transistor M1, a data write transistor M2, a threshold compensation transistor M3, a first light emission control transistor M4, a second light emission control transistor M5, a first initialization transistor M6, a second initialization transistor M7, a storage capacitor Cst and a coupling capacitor C0. The threshold compensation transistor M3 and the first initialization transistor M6 are IGZO transistors and each have four terminals (that is, a gate, a source, a drain and a compensation electrode). A direct current voltage VDC is applied to the compensation electrode, so that a threshold voltage of the IGZO transistor is compensated for, and the PBTS of the IGZO transistor is reduced, which is conducive to improving the reliability of the pixel circuit and then ensuring the display effect of the display panel. The specific working principle of the pixel circuit is not repeated here.

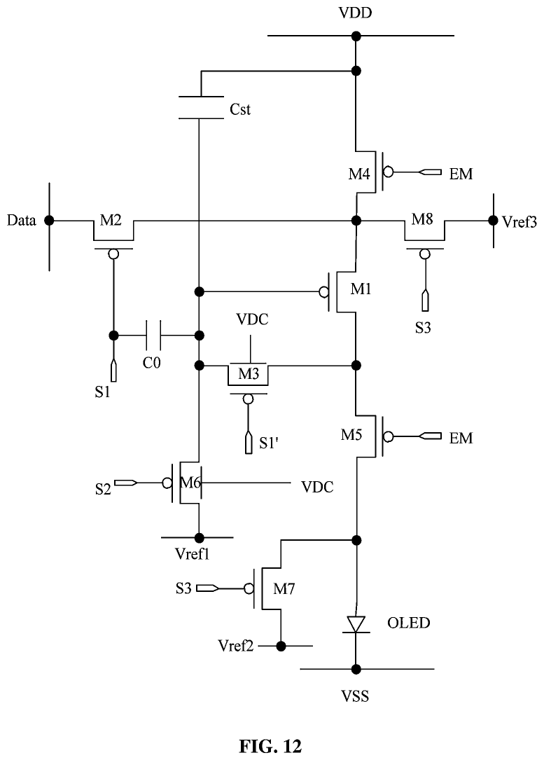

FIG. 12 is a structural diagram of another pixel circuit according to an embodiment of the present application. The pixel circuit includes an organic light-emitting diode OLED, a drive transistor M1, a data write transistor M2, a threshold compensation transistor M3, a first light emission control transistor M4, a second light emission control transistor M5, a first initialization transistor M6, a second initialization transistor M7, a third initialization transistor M8, a storage capacitor Cst and a coupling capacitor C0. The threshold compensation transistor M3 and the first initialization transistor M6 are IGZO transistors and each have four terminals (that is, a gate, a source, a drain and a compensation electrode). A direct current voltage VDC is applied to the compensation electrode, so that a threshold voltage of the IGZO transistor is compensated for, and the PBTS of the IGZO transistor is reduced, which is conducive to improving the reliability of the pixel circuit and then ensuring the display effect of the display panel. The specific working principle of the pixel circuit is not repeated here.

In the embodiment, the direct current voltage VDC connected to the IGZO transistor may be a power supply voltage VSS, or may be an initialization voltage Vref (including Vref1, Vref2 and Vref3) The power supply voltage VSS may be provided by a power supply line, and the initialization voltage Vref may be provided by an initialization signal line.

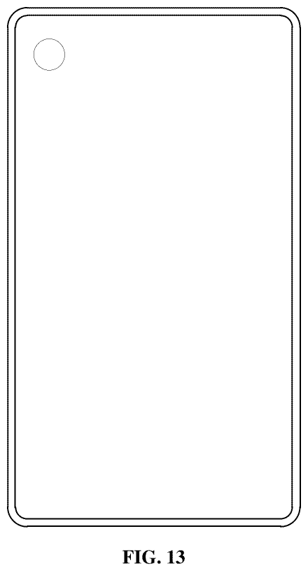

FIG. 13 is a structural diagram of a display panel according to an embodiment of the present application. The display panel may be applied to tablets, mobile phones, watches and wearable devices, as well as all other display-related electronic products such as vehicle-mounted displays, camera displays, televisions and computer screens. The display panel includes the array substrate provided in any embodiment of the present application; therefore, the display device provided in the embodiment of the present application has the beneficial effects described in any embodiment of the present application.

It is to be understood that various forms of processes shown above may be adopted with steps reordered, added or deleted. For example, the steps described in the present application may be performed in parallel, sequentially or in different sequences, as long as the desired results of the embodiment of the present application can be achieved, and no limitation is imposed herein.

The preceding embodiments do not limit the scope of the present application. It is to be understood by those skilled in the art that various modifications, combinations, sub-combinations and substitutions may be performed according to design requirements and other factors. Any modification, equivalent substitution, improvement or the like made within the spirit and principle of the present application is within the scope of the present application.

What is claimed is:

1. An array substrate, comprising:
a substrate;
a compensation layer disposed on a side of the substrate;
an insulating layer disposed on a side of the compensation layer away from the substrate and covering the compensation layer; and
an active layer disposed on a side of the insulating layer away from the substrate;
wherein a vertical projection of the compensation layer on the substrate overlaps a vertical projection of the active layer on the substrate, and the compensation layer is configured to compensate for a threshold voltage of a thin-film transistor of the array substrate.

2. The array substrate according to claim 1, wherein the vertical projection of the compensation layer on the substrate overlaps at least the vertical projection of the active layer on the substrate.

3. The array substrate according to claim 1, wherein the compensation layer is made of a conductive material and configured to be connected to a compensation voltage.

4. The array substrate according to claim 3, wherein the compensation voltage is a negative voltage.

5. The array substrate according to claim 1, wherein a material of the active layer comprises a metal oxide.

6. The array substrate according to claim 1, wherein a material of the compensation layer comprises amorphous silicon.

7. The array substrate according to claim 1, further comprising a gate layer and a gate insulating layer, wherein,
the gate insulating layer is disposed on a side of the insulating layer away from the substrate and covers a surface of the gate layer, and the active layer is disposed on a side surface of the gate insulating layer away from the gate layer; and
a non-overlapping portion exists between a vertical projection of the gate layer on the substrate and the vertical projection of the active layer on the substrate, and the vertical projection of the compensation layer on the substrate covers at least the non-overlapping portion.

8. The array substrate according to claim 1, further comprising a gate layer, a gate insulating layer and an interlayer insulating layer, wherein,
the active layer is disposed on a side surface of the insulating layer away from the substrate;
the gate insulating layer is disposed on a side of the active layer away from the substrate and covers the active layer;
the gate layer is disposed on a side surface of the gate insulating layer away from the active layer; and
the interlayer insulating layer is disposed on a side of the gate insulating layer away from the insulating layer and covers the gate layer.

9. The array substrate according to claim 1, further comprising a first gate insulating layer, a second gate insulating layer and an interlayer insulating layer which are laminated on the insulating layer and a gate layer comprising a first gate layer and a second gate layer; wherein,
a non-overlapping portion exists between a vertical projection of the first gate layer on the substrate and the vertical projection of the active layer on the substrate, and the vertical projection of the compensation layer on the substrate covers at least the non-overlapping portion;
the first gate layer is disposed on a side surface of the insulating layer away from the substrate and is covered by the first gate insulating layer;
the second gate insulating layer covers the active layer; and
the second gate layer is disposed on a side surface of the second gate insulating layer away from the first gate insulating layer and is covered by the interlayer insulating layer.

10. The array substrate according to claim 9, wherein the active layer comprises a channel region, a source region and a drain region, the source region and the drain region are disposed on two sides of the channel region respectively, and
the array substrate further comprises a source layer configured to be connected to the source region and a drain layer configured to be connected to the drain region.

11. The array substrate according to claim 9, wherein the first gate layer is configured to be connected to the second gate layer; or the first gate layer is configured to be connected to a source layer; or the second gate layer is configured to be connected to a source layer.

12. The array substrate according to claim 1, wherein the insulating layer comprises a first insulating sublayer, a second insulating sublayer and a third insulating sublayer which are laminated on a side of the substrate; the compensation layer is disposed in one layer of the first insulating sublayer, the second insulating sublayer and the third insulating sublayer; and
the array substrate further comprises a first electrode layer and a second electrode layer.

13. The array substrate according to claim 12, wherein,
the first electrode layer is disposed on a side of the first insulating sublayer away from the substrate and is covered by the second insulating sublayer, and
the second electrode layer is disposed on a side of the second insulating sublayer away from the first insulating sublayer and is covered by the third insulating sublayer.

14. The array substrate according to claim 12, wherein the first electrode layer is disposed in a same layer as the compensation layer, and the second electrode layer is disposed in a same layer as the gate layer.

15. The array substrate according to claim 12, further comprising a blocking layer disposed in one layer of the first insulating sublayer, the second insulating sublayer and the third insulating sublayer.

16. The array substrate according to claim 15, wherein the compensation layer is disposed in a same layer as the blocking layer.

17. A display panel, comprising an array substrate, wherein a pixel circuit is disposed on the array substrate; wherein the array substrate comprises: a substrate; a compensation layer disposed on a side of the substrate; an insulating layer disposed on a side of the compensation layer away from the substrate and covering the compensation layer; and an active layer disposed on a side of the insulating layer away from the substrate; wherein a vertical projection of the compensation layer on the substrate overlaps a vertical projection of the active layer on the substrate, and the compensation layer is configured to compensate for a threshold voltage of a thin-film transistor of the array substrate.

18. The display panel according to claim 17, further comprising:
a power supply line configured to provide a power supply voltage for the pixel circuit; and
an initialization signal line configured to provide an initialization voltage for the pixel circuit;
wherein the compensation layer is connected to the power supply line or the initialization signal line.

19. The display panel according to claim 17, wherein the vertical projection of the compensation layer on the substrate overlaps at least the vertical projection of the active layer on the substrate.

20. The display panel according to claim 17, wherein the compensation layer is made of a conductive material and configured to be connected to a compensation voltage.
